(19) United States
(12) Patent Application Publication
(10) Pub. No.: US 2011/0215746 A1
(43) Pub. Date: Sep. 8, 2011

(54) SEMICONDUCTOR DEVICE

(75) Inventors: Ayanori IKOSHI, Kyoto (JP); Hiroto YAMAGIWA, Hyogo (JP); Shingo HASHIZUME, Kyoto (JP); Manabu YANAGIHARA, Osaka (JP); Yasuhiro UEMOTO, Toyama (JP)

(73) Assignee: PANASONIC CORPORATION, Osaka (JP)

(21) Appl. No.: 13/036,207

(22) Filed: Feb. 28, 2011

(30) Foreign Application Priority Data
Mar. 2, 2010 (JP) 2010-045966

(51) Int. Cl. H02P 6/14; H03K 3/021

(52) U.S. Cl. 318/400.27; 327/333

(57) ABSTRACT

A semiconductor device according to the present invention is a semiconductor device which includes: a semiconductor element; a gate drive circuit; and a connection terminal unit, wherein the semiconductor element includes: a gate electrode pad; and first and second ohmic electrode pads, the connection terminal includes: a first ohmic electrode terminal connected to the first ohmic electrode pad; a second ohmic electrode terminal connected to the second ohmic electrode pad; a gate drive terminal connected to the first ohmic electrode pad; and a gate terminal connected to the gate electrode pad, an input terminal of the gate drive circuit is connected to the gate drive terminal, an output terminal of the gate drive circuit is connected to the gate terminal, and a potential of the first ohmic electrode pad corresponds to a reference potential of the gate drive circuit.

### BACKGROUND OF THE INVENTION

(1) Field of the Invention

The present invention relates to semiconductor devices which perform power conversion, and particularly to a current-driven semiconductor device including a nitride semiconductor.

(2) Description of the Related Art

In the context of the global warming issue, further increase in energy efficiencies of electrical apparatuses has been expected, and increase in power conversion efficiencies of power conversion devices such as power circuits and inverter circuits which handle a large amount of electric power has been required. The biggest factor in determination of the power conversion efficiencies of the power conversion devices is losses at power semiconductor elements such as insulated gate bipolar transistors (IGBTs) and metal oxide semiconductor field effect transistors (MOSFETs) that are used for the power conversion. Reducing the losses at the power semiconductor elements makes it possible to significantly increase the power conversion efficiencies of the power conversion devices. Examples of the losses caused in the power semiconductor elements include conduction losses caused when currents are passed to the elements and switching losses caused when the elements perform switching. Using elements having a small on resistance reduces the conduction losses, and using elements which perform switching at a higher speed reduces the switching losses. As a result, high-speed switching and low on resistance power semiconductor elements have been developed.

However, it has been increasingly difficult to further reduce the on resistance and increase the switching speed, because currently-available power semiconductor elements are made of silicon (Si) and are almost getting to material limit of Si. In order to overcome the material limit of Si and reduce the conduction losses and the switching losses, use of nitride system semiconductors represented by gallium nitride or so-called wide band gap semiconductor elements such as silicon carbide (SiC) has been considered. The wide band gap semiconductor elements have a dielectric breakdown electric field approximately one digit higher than that of Si, and especially charges are generated at a heterojunction interface between aluminum gallium nitride (AlGaN) and gallium nitride (GaN) through spontaneous polarization and piezo polarization. With this, even at the time of undoping, a two-dimensional electron gas (2 DEG) layer having the sheet carrier density of 1×10¹³ cm⁻² or above and the high mobility of 1000 cm²V/sec or above is formed. For this reason, AlGaN/GaN heterojunction field effect transistors (hereinafter, described as GaN transistors) have been expected as power switching transistors which achieve the low on resistance and high voltage capability.

The GaN transistors are far superior to conventional Si devices in terms of potential characteristics. For instance, the GaN transistors have a short period of rise and fall such as approximately several tens of ns, and can switch a high current ranging from several tens of A to several hundreds of A. However, when performing high-speed and high-current switching, the GaN transistors are affected by parasitic inductance L of a connecting wire to a chip, leads of a package, and a wiring pattern. A voltage noise defined by L×di/dt is generated at a gate of the GaN transistors, and this generation causes a gate malfunction such as false detection of a gate. Thus, in order to utilize the high-speed and high-current switching characteristic of the GaN transistors, indispensable is a method for suppressing gate malfunction.

FIG. 12 is a circuit configuration diagram illustrating a drive circuit of a conventional IGBT disclosed in Patent Reference 1 (Japanese Patent No. 3008924). The drive circuit in the diagram includes a protection circuit which has a protection function against an overcurrent and temperature rise. A power GND terminal 551 which branches off from an output terminal of an IGBT 516 and a sense GND terminal 552 are placed in the drive circuit so that the IGBT 516, which is a power element of the drive circuit, suppresses gate malfunction caused by a gate voltage which has passed through the protection circuit. Here, the power GND terminal 551 is a terminal at which a reference potential of a power line, which is an outward path of a drive current flowing between a source and a drain, is detected, and the sense GND terminal 552 is a terminal at which a reference potential for measuring a voltage at an input terminal of the protection circuit is detected.

The power GND terminal 551 is placed on a current path of the drive current which flows when the IGBT 516 is driven. In contrast, the sense GND terminal 552 is placed on a current path which defines a GND level of the protection circuit which monitors an operating status of the IGBT 516.

More specifically, the protection circuit determines whether or not overcurrent protection is necessary by comparing, in a comparator 579, a voltage of a sense terminal 553 for monitoring the overcurrent and a threshold voltage defined by a reference voltage source 581. Thus, the protection circuit needs a sense GND line 576 for defining the above voltages which are input voltages to the comparator 579. For this reason, the sense GND line 576 is a wire which branches off from the power line, and is connected to a power GND line 567 via an impedance (resistor 584). In other words, a sense GND for the protection circuit is separately provided on the power GND line 567.

To put it differently, the sense GND terminal 552 is connected via the impedance to the power GND line at a location which is, viewed from a side where the power element is connected, farther than a location of a wiring pattern to which the protection circuit is connected. With this, a voltage transiently generated by a parasitic inductance 585 of the power line in the power GND line 567 is suppressed by the impedance (resistor 584). As a result, an appropriate protection operation by the protection circuit is ensured, which allows the drive circuit including the IGBT 516 to operate stably.

However, it is necessary to separately provide the sense GND line 576 and the sense GND terminal 552 for accurately monitoring a sense voltage from the IGBT 516 in the drive circuit disclosed in Patent Reference 1.

Furthermore, although the sense GND line 576 has a tail-end part connected to the impedance (resistor 584), the sense GND line 576 is not completely independent from the power GND line 567, because the sense GND line 576 branches off from the power line. Thus, there is a probability that a voltage noise generated in a transient state, which is a time of switching on and off the IGBT 516, is also generated by an internal inductance 583 of the sense GND line 576, and there is a probability that the sense voltage still includes the voltage noise.

In particular, a current-driven switching power device including a wide band gap semiconductor such as GaN (gallium nitride) and SiC (silicon carbide) allows high-speed and high-current operations because of very small parasitic capacitance, but an operation threshold voltage of a gate is very low such as approximately 1 V. Thus, when the drive circuit disclosed in Patent Reference 1 is applied to, especially, the above current-driven GaN or SiC power device having the low threshold voltage, the voltage noise needs to be strictly suppressed. Otherwise, the voltage noise generated at the gate or in the gate drive circuit by the influence of the parasitic inductance in the transient state causes the gate malfunction such as the false detection of the gate, and an effect of preventing the malfunction is suppressed.

Moreover, when gate drive circuits represented by the protection circuit are formed and an output current of the power element is controlled with high accuracy or in a complex manner, as in the drive circuit disclosed in Patent Reference 1, defining a reference potential of the protection circuit, which is the gate drive circuit, by GND of a power line limits independent operations of the gate drive circuits.

### SUMMARY OF THE INVENTION

The present invention has been devised in view of the above problems, and has an object to provide a semiconductor device which makes it possible to reduce a disturbance noise generated to the gate or the gate drive circuit of the current-driven semiconductor device by the parasitic inductance, and to increase accuracy and stability of gate drive.

In order to solve the above problems, a semiconductor device according to a first aspect of the present invention includes: a first semiconductor element which is current driven and performs power conversion; a first gate drive circuit which controls the power conversion by the first semiconductor element; and a connection terminal unit, wherein the first semiconductor element includes: a stacked structure including nitride semiconductor layers stacked above a substrate; a gate electrode formed on the stacked structure; a first ohmic electrode and a second ohmic electrode each of which is formed, above the substrate, on a different side of the gate electrode; a gate electrode pad wired from the gate electrode on the first semiconductor element; and a first ohmic electrode pad and a second ohmic electrode pad respectively wired from the first ohmic electrode and the second ohmic electrode on the first semiconductor element, wherein the connection terminal unit includes: a first ohmic electrode terminal connected to the first ohmic electrode pad through a first connection material; a second ohmic electrode terminal connected to the second ohmic electrode pad through a second connection material; a gate drive terminal connected to the first ohmic electrode pad through a third connection material; and a gate terminal connected to the gate electrode pad through a fourth connection material, and an input terminal and an output terminal of the first gate drive circuit are respectively connected to the gate drive terminal and the gate terminal, and a potential of the first ohmic electrode pad corresponds to a reference potential of the first gate drive circuit.

With this configuration, a power line and a gate drive line form separate current lines, the power line including the first semiconductor element, the first ohmic electrode pad, the first connection material, the first ohmic electrode terminal, an external power supply, a load, the second ohmic electrode terminal, the second connection material, and the second ohmic electrode pad, and the gate drive line including the first semiconductor element, the first ohmic electrode pad, the third connection material, the gate drive terminal, the gate drive circuit, the gate terminal, the fourth connection material, and the gate electrode pad. In addition, the input terminal of the gate drive circuit is electrically connected to the first ohmic electrode pad through the third connection material, and thus the potential of the first ohmic electrode pad corresponds to the reference potential of the gate drive circuit which is current driven.

In the semiconductor device according to the first aspect of the present invention, it is not necessary to separately provide a GND terminal of the gate drive circuit to other paths of the power line and the gate drive line. Accordingly, the gate drive line is not influenced by a voltage noise generated in a transient state of the first semiconductor element by a parasitic inductance of the power line, and thus the gate drive circuit makes it possible to perform highly accurate and stable gate drive.

Furthermore, the connection terminal unit may further include a first substrate terminal joined to the first semiconductor element, and the gate drive terminal may be identical to the first substrate terminal.

According to the first aspect, this successfully stabilizes the substrate potential of the nitride semiconductor element, which becomes the very effective measures against the disturbance noise.

Moreover, the semiconductor device may further include: a second semiconductor element having a same structure as the first semiconductor element; and a second gate drive circuit having a same structure as the first gate drive circuit, wherein a connection relationship between the second semiconductor element and the second gate drive circuit may be the same as a connection relationship between the first semiconductor element and the first gate drive circuit, and the first semiconductor element, the second semiconductor element, the first gate drive circuit, and the second gate drive circuit may form a first half bridge by connecting the first ohmic electrode terminal of the first semiconductor element and the second ohmic electrode terminal of the second semiconductor element.

In the semiconductor device according to the first aspect of the present invention, it is possible to apply a structure in which the semiconductor element and the gate drive circuit are formed into one unit, to a half bridge in which two such units are connected in series to each other. In this configuration also, the gate drive circuit makes it possible to perform the highly accurate and stable gate drive.

Furthermore, the semiconductor device may further include a second half bridge which is connected in parallel to the first half bridge and has a same structure as the first half bridge, wherein the semiconductor device may function as a motor drive inverter which drives a single-phase motor.

The semiconductor device according to the first aspect of the present invention may function as a single-phase driven inverter circuit including the half bridge in which the two units are connected in parallel to each other. This achieves stable drive of a single-phase motor for which malfunction is reduced.

Moreover, the semiconductor device may further include a second half bridge and a third half bridge which are connected in parallel to the first half bridge and have a same structure as the first half bridge, wherein the semiconductor device may function as a motor drive inverter which drives a three-phase motor.

The semiconductor device according to the first aspect of the present invention may function as a three-phase driven inverter circuit including the half bridge in which three such units are connected in parallel to each other. This achieves stable drive of a three-phase motor for which malfunction is reduced.

Furthermore, in order to solve the above problems, a semiconductor device according to a second aspect of the present invention includes: a third semiconductor element which is current driven and performs power conversion; a third gate drive circuit and a fourth gate drive circuit which control the power conversion by the third semiconductor element; and a connection terminal unit, wherein the third semiconductor element includes: a stacked structure including nitride semiconductor layers stacked above a substrate; a first gate electrode and a second gate electrode formed adjacent to each other on the stacked structure; a third ohmic electrode and a fourth ohmic electrode each of which is formed, above the substrate, on a different side of the first gate electrode and the second gate electrode; a first gate electrode pad and a second gate electrode pad respectively wired from the first gate electrode and the second gate electrode on the third semiconductor element; and a third ohmic electrode pad and a fourth ohmic electrode pad respectively wired from the third ohmic electrode and the fourth ohmic electrode on the third semiconductor element, the connection terminal unit includes: a third ohmic electrode terminal connected to the third ohmic electrode pad through a first connection material; a fourth ohmic electrode terminal connected to the fourth ohmic electrode pad through a second connection material; a first gate drive terminal connected to the third ohmic electrode pad through a third connection material; a second gate drive terminal connected to the fourth ohmic electrode pad through a fourth connection material; a first gate terminal connected to the first gate electrode pad through a fifth connection material; and a second gate terminal connected to the second gate electrode pad through a sixth connection material, an input terminal and an output terminal of the third gate drive circuit are respectively connected to the first gate drive terminal and the first gate terminal, and a potential of the third ohmic electrode pad corresponds to a reference potential of the third gate drive circuit, and an input terminal and an output terminal of the fourth gate drive circuit are respectively connected to the second gate drive terminal and the second gate terminal, and a potential of the fourth ohmic electrode pad corresponds to a reference potential of the fourth gate drive circuit.

With this configuration, a power line and a first gate drive line form separate current lines, the power line including the third semiconductor element which is a double-gate type, the third ohmic electrode pad, the first connection material, the third ohmic electrode terminal, an external power supply, a load, the second connection material, and the fourth ohmic electrode terminal, the first gate drive line including the third semiconductor element, the third ohmic electrode pad, the third connection material, the first gate drive terminal, the third gate drive circuit, the first gate terminal, the fifth connection material, and the first gate electrode pad. In addition, the power line and a second gate drive line form separate current lines, the second gate drive line including the third semiconductor element, the fourth ohmic electrode pad, the fourth connection material, the second gate drive terminal, the fourth gate drive circuit, the second gate terminal, the sixth connection material, and the second gate electrode pad. Moreover, the input terminal of the third gate drive circuit is electrically connected to the third ohmic electrode pad through the third connection material, and thus the potential of the third ohmic electrode pad corresponds to the reference potential of the third gate drive circuit which is current driven. Furthermore, the input terminal of the fourth gate drive circuit is electrically connected to the fourth ohmic electrode pad through the fourth connection material, and thus the potential of the fourth ohmic electrode pad corresponds to the reference potential of the fourth gate drive circuit which is current driven.

In the semiconductor device according to the second aspect of the present invention, it is not necessary to separately provide a GND terminal of the gate drive circuit to other paths of the power line and the first and second gate drive lines. Moreover, the gate drive line is not influenced by a voltage noise generated in a transient state of the third semiconductor element by a parasitic inductance of the power line, and thus the third and fourth gate drive circuits make it possible to perform highly accurate and stable gate drive.

Furthermore, the semiconductor device may further include: a fourth semiconductor element having a same structure as the third semiconductor element; a fifth gate drive circuit having a same structure as the third gate drive circuit; and a sixth gate drive circuit having a same structure as the fourth gate drive circuit, wherein a connection relationship between the fourth semiconductor element and the fifth gate drive circuit is the same as a connection relationship between the third semiconductor element and the third gate drive circuit, a connection relationship between the fourth semiconductor element and the sixth gate drive circuit is the same as a connection relationship between the third semiconductor element and the fourth gate drive circuit, and the third semiconductor element, the fourth semiconductor element, the third gate drive circuit, the fourth gate drive circuit, the fifth gate drive circuit, and the sixth gate drive circuit form a fourth half bridge by connecting the third ohmic electrode terminal of the third semiconductor element and the fourth ohmic electrode terminal of the fourth semiconductor element.

In the semiconductor device according to the second aspect of the present invention, it is possible to apply a structure in which the semiconductor element which is a double-gate type and the two gate drive circuits are formed into one unit, to a half bridge in which two such units are connected in series to each other. In this configuration also, the third and fourth gate drive circuits make it possible to perform the highly accurate and stable gate drive.

Moreover, the semiconductor device may further include a fifth half bridge which is connected in parallel to the fourth half bridge and has a same structure as the fourth half bridge, wherein the semiconductor device functions as a motor drive inverter which drives a single-phase motor.

The semiconductor device according to the second aspect of the present invention may function as a single-phase driven inverter circuit including the half bridge in which the two units are connected in parallel to each other. This achieves stable drive of a single-phase motor for which malfunction is reduced.

Furthermore, the semiconductor device may further include a fifth half bridge and a sixth half bridge which are connected in parallel to the fourth half bridge and have a same structure as the fourth half bridge, wherein the semiconductor device functions as a motor drive inverter which drives a three-phase motor.

The semiconductor device according to the second aspect of the present invention may function as a three-phase driven inverter circuit including the half bridge in which three such units are connected in parallel to each other. This achieves stable drive of a three-phase motor for which malfunction is reduced.

Moreover, the semiconductor device may further include fourth to eleventh semiconductor elements having a same structure as the third semiconductor element, wherein each of the fourth to eleventh semiconductor elements is connected to a gate drive circuit having a same structure as the third gate drive circuit and a gate having a same structure as the fourth gate drive circuit, the fourth ohmic electrode terminal of each of the third, sixth, and ninth semiconductor elements is connected to a first output terminal of a three-phase alternating-current power supply, the fourth ohmic electrode terminal of each of the fourth, seventh, and tenth semiconductor elements is connected to a second output terminal of the three-phase alternating-current power supply, the fourth ohmic electrode terminal of each of the fifth, eighth, and eleventh semiconductor elements is connected to a third output terminal of the three-phase alternating-current power supply, the third ohmic electrode terminal of each of the third, fourth, and fifth semiconductor elements is connected to a first input terminal of a three-phase motor, the third ohmic electrode terminal of each of the sixth, seventh, and eighth semiconductor elements is connected to a second input terminal of the three-phase motor, the third ohmic electrode terminal of each of the ninth, tenth, and eleventh semiconductor elements is connected to a third input terminal of the three-phase motor, and the semiconductor device functions as a motor drive matrix converter which drives the three-phase motor.

The semiconductor device according to the second aspect of the present invention may function as a three-phase driven matrix converter circuit in which structures in each of which the semiconductor element which is a double-gate type and the two gate drive circuits are formed into one unit are arranged in matrix. It is preferred that the reference potential of each unit corresponds not to a reference potential of a drive system but to an arbitrary reference potential, because the reference potential of the drive system varies when an input power supply is an AC power supply. According to the above configuration, the potential of the third or fourth ohmic electrode pad, which is a current-driven source pad, corresponds to the reference potential of each unit, and thus the reference potential of each unit does not need to be identical to the reference potential of the semiconductor device, and it is possible to operate the gate drive circuits independently.

In the semiconductor device according to the present invention, the power line and the gate drive line form the separate current lines, and the potential of the source pad of the semiconductor element which is current driven and the potential of the gate drive terminal correspond to the reference potential of the gate drive circuit, and thus it is possible to reduce a disturbance noise generated by a parasitic inductance.

### FURTHER INFORMATION ABOUT TECHNICAL BACKGROUND TO THIS APPLICATION

The disclosure of Japanese Patent Application No. 2010-045966 filed on Mar. 2, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a top view illustrating a connection of a semiconductor device according to Embodiment 1 of the present invention;

FIG. 1B is an equivalent circuit diagram of a chief part of the semiconductor device according to Embodiment 1 of the present invention;

FIG. 2A is a top view illustrating a semiconductor element according to Embodiment 1 of the present invention;

FIG. 2B is a cross-sectional view taken along the line X-X′ of the semiconductor element illustrated in FIG. 2A;

FIG. 2C is a cross-sectional view taken along the line Y-Y′ of the semiconductor element illustrated in FIG. 2A;

FIG. 3 is a circuit configuration diagram showing a semiconductor device according to Embodiment 2 of the present invention;

FIG. 4 is an equivalent circuit diagram of a chief part of a half bridge according to Embodiment 2 of the present invention;

FIG. 5 is a circuit configuration diagram showing a modification of the semiconductor device according to Embodiment 2 of the present invention;

FIG. 6A is a top view illustrating a connection of a semiconductor device according to Embodiment 3 of the present invention;

FIG. 6B is an equivalent circuit diagram of a chief part of the semiconductor device according to Embodiment 3 of the present invention;

FIG. 7A is a top view illustrating a semiconductor element according to Embodiment 3 of the present invention;

FIG. 7B is a cross-sectional view taken along the line X-X′ of the semiconductor element illustrated in FIG. 7A;

FIG. 7C is a cross-sectional view taken along the line Y-Y′ of the semiconductor element illustrated in FIG. 7A;

FIG. 8 is a circuit configuration diagram showing a semiconductor device according to Embodiment 4 of the present invention;

FIG. 9 is an equivalent circuit diagram of a chief part of a half bridge according to Embodiment 4 of the present invention;

FIG. 10 is a circuit configuration diagram showing a first modification of the semiconductor device according to Embodiment 4 of the present invention;

FIG. 11 is a circuit configuration diagram showing a second modification of the semiconductor device according to Embodiment 4 of the present invention; and

FIG. 12 is a circuit configuration diagram illustrating a drive circuit of a conventional IGBT disclosed in Patent Reference 1.

### DESCRIPTION OF THE PREFERRED EMBODIMENT(S)

The following describes embodiments of a semiconductor device of the present invention with reference to the drawings.

### Embodiment 1

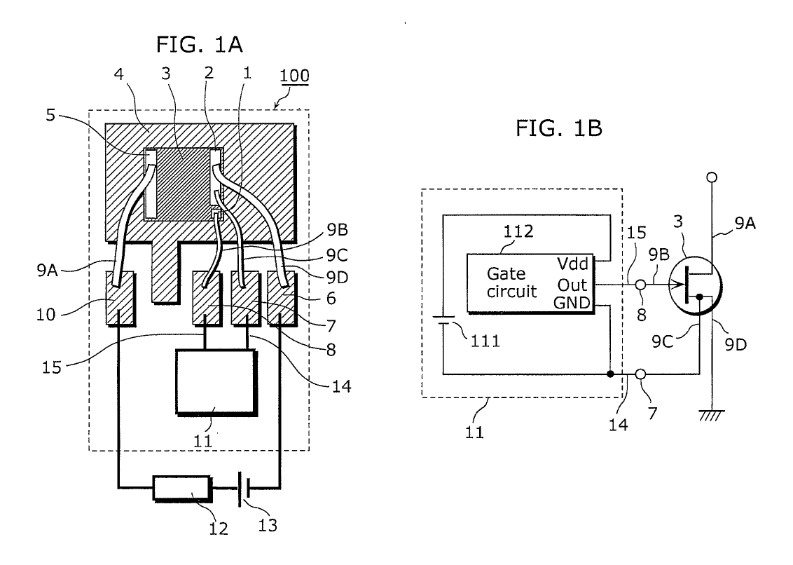

FIG. 1A is a top view illustrating a connection of a semiconductor device according to Embodiment 1 of the present invention. A semiconductor device 100 shown in the view includes: a semiconductor element 3 which is a first semiconductor element; bonding wires 9A to 9D which are connection materials; and a gate drive circuit 11. Furthermore, a substrate terminal 4 which is a first substrate terminal, an ohmic electrode terminal 6 and an ohmic electrode terminal 10 which are respectively a first ohmic electrode terminal and a second ohmic electrode terminal, a gate drive terminal 7, and a gate terminal 8 are placed in an upper portion of the semiconductor device 100 in a manner such that they separate from each other. They compose a connection terminal unit. Moreover, the semiconductor element 3 is joined onto the substrate terminal 4, and a gate electrode pad 1, and an ohmic electrode pad 2 and an ohmic electrode pad 5 which are respectively a first ohmic electrode pad and a second ohmic electrode pad are placed on the semiconductor element 3 in a manner such that they separate from each other.

The ohmic electrode pad 5 is electrically connected to the ohmic electrode terminal 10 through the bonding wire 9A. Furthermore, the ohmic electrode pad 2 is electrically connected to the ohmic electrode terminal 6 through the bonding wire 9D, and is also separately connected to the gate drive terminal 7 through the bonding wire 9C. Moreover, the gate electrode pad 1 is electrically connected to the gate terminal 8 through the bonding wire 9B. The bonding wires 9A to 9D are made of, for example, Al.

The ohmic electrode terminal 10 is electrically connected to one of terminals of a load 12, and the ohmic electrode terminal 6 is electrically connected to an anode of a DC power supply 13. Furthermore, the other one of the terminals of the load 12 is electrically connected to a cathode of the DC power supply 13. With the above connections, the semiconductor element 3, the ohmic electrode pad 2, which is placed on the semiconductor element 3, the bonding wire 9D, the ohmic electrode terminal 6, the DC power supply 13, the load 12, the ohmic electrode terminal 10, the bonding wire 9A, and the ohmic electrode pad 5 compose a power line in which a drain current of the semiconductor element.

The gate drive circuit 11 includes an output terminal 15, a reference potential terminal 14 which is an input terminal, and a DC power supply for driving the gate drive circuit (not shown). The output terminal 15 is electrically connected to the gate terminal 8, and the reference potential terminal 14 is electrically connected to the gate drive terminal 7. With the above connections, the semiconductor element 3, the ohmic electrode pad 2, the bonding wire 9C, the gate drive terminal 7, the gate drive circuit 11, the gate terminal 8, the bonding wire 9B, and the gate electrode pad 1 compose a gate drive line. In other words, the gate drive circuit 11 is a first gate drive circuit which receives a gate-source current, which is defined by a gate-source resistance of the semiconductor element 3, through the ohmic electrode pad 2, the bonding wire 9C, and the gate drive terminal 7, and which determines, using the received current, an electrical signal which is for controlling power conversion by the semiconductor element 3 and which is to be provided to the gate.

FIG. 1B is an equivalent circuit diagram of a chief part of the semiconductor device according to Embodiment 1 of the present invention. The gate drive circuit 11 is a current-driven circuit which includes a DC power supply 111 and a gate circuit 112. A cathode of the DC power supply 111 is electrically connected to a power supply terminal Vdd of the gate circuit 112, and an anode of the DC power supply 111 is electrically connected to a reference potential terminal GND of the gate circuit 112. In this case, the above power line illustrated in FIG. 1A and the above gate drive line form separate current lines. Moreover, the reference potential terminal 14 of the gate drive circuit 11 is electrically connected to the ohmic electrode pad 2 through the bonding wire 9C, and thus a potential of the ohmic electrode pad 2 corresponds to a reference potential of the gate drive circuit 11 which is current driven.

With this, it is unnecessary to separately provide a GND terminal of the gate drive circuit to other paths of the power line and the gate drive line in the semiconductor device 100. Furthermore, the gate drive line is not influenced by a voltage noise generated in a transient state of the semiconductor element 3 by a parasitic inductance of the power line, and thus the gate drive circuit 11 makes it possible to perform highly accurate and stable gate drive.

It is to be noted that in the above structure, although the potential of the ohmic electrode pad 2 corresponds to the reference potential of the gate drive circuit 11 and it is possible to set the potential of the ohmic electrode pad 2 independently of a GND potential of the semiconductor device 100, the potential of the ohmic electrode pad 2 may correspond to the GND potential of the semiconductor device 100 depending on use and configuration of the gate drive circuit 11. In this case also, it is possible to produce the same effects as effects obtained through the structure. In addition, it is possible to stabilize a substrate potential of the semiconductor device 100, which is very effective as measures against disturbance noise.

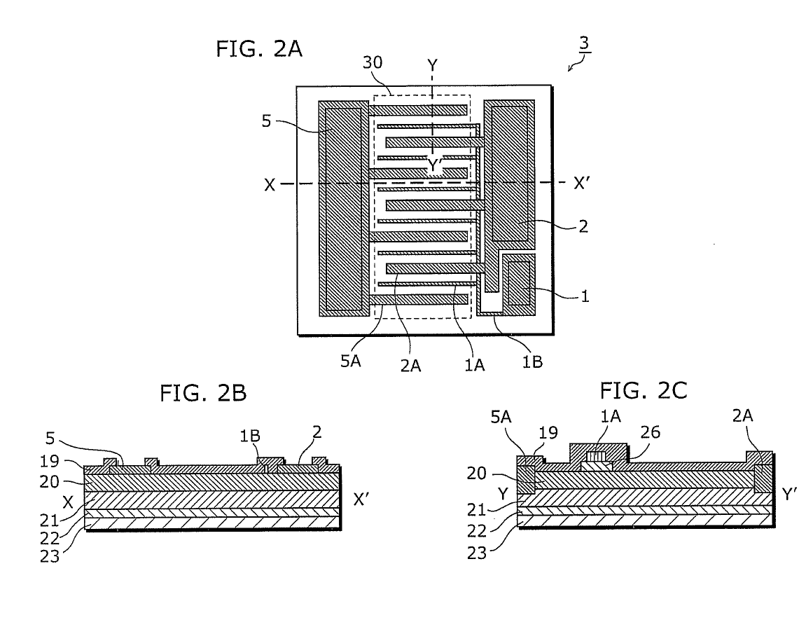

FIG. 2A is a top view illustrating the semiconductor element according to Embodiment 1 of the present invention. FIG. 2B is a cross-sectional view taken along the line X-X′ of the semiconductor element illustrated in FIG. 2A. FIG. 2C is a cross-sectional view taken along the line Y-Y′ of the semiconductor element illustrated in FIG. 2A. The semiconductor element 3 illustrated in FIG. 2A is, for instance, a nitride semiconductor element in which a two-dimensional electron gas (2 DEG) including heterojunction of AlGaN/GaN is used as a channel.

As shown in FIGS. 2A to 2C, in the semiconductor element 3, a buffer layer 22, a nitride semiconductor layer 21, a nitride semiconductor layer 20, and a p-type nitride semiconductor layer 26 are sequentially stacked on a substrate 23, a gate electrode 1A and ohmic electrodes 2A and 5A are formed, and a protective film 19 is formed. The buffer layer 22, the nitride semiconductor layer 21, the nitride semiconductor layer 20, and the p-type nitride semiconductor layer 26 form a stacked structure of a nitride semiconductor layer. The ohmic electrode pad 5 is connected to the ohmic electrode 5A, which is the second ohmic electrode, the ohmic electrode pad 2 is connected to the ohmic electrode 2A, which is the first ohmic electrode, and the gate electrode pad 1 is connected to the gate electrode 1A through a gate wire 1B. Each of the ohmic electrode pad 5, the ohmic electrode pad 2, and the gate electrode pad 1 is formed in an opening of the protective film 19. Moreover, the ohmic electrode 5A, the ohmic electrode 2A, and the gate electrode 1A form, in an active region 30, a finger shape as shown in FIG. 2A. In other words, the gate electrode 1A is placed between the ohmic electrodes 5A and 2A. The semiconductor element 3 having the above structure is, for example, a switching element which switches on and off a power line to which the DC power supply 13 shown in FIG. 1A applies the voltage value of 300 V to pass the current of approximately 10 A.

The nitride semiconductor element as shown in FIGS. 2A to 2C has a very small parasitic capacitance between each of terminals such as several tens of pF to several hundreds of pF, and thus enables high-speed switching at a several tens of ns to several hundreds of ns level in comparison with a MOSFET or an IGBT. However, the faster the above switching is, the more a voltage noise, which is a product of a parasitic inductance L of, for instance, a wire, a lead, and a wiring pattern and di/dt, is generated. As stated above, the voltage noise causes malfunction such as false detection of a gate in gate drive, and thus it is necessary to reduce the voltage noise.

In order to reduce the above voltage noise, as shown in FIG. 1A, more specifically, the potential of ohmic electrode pad 2 corresponds to the reference potential of the gate drive circuit 11. Separating a current path from the ohmic electrode pad 2 through the bonding wire 9D to the ohmic electrode terminal 6 and a current path from the ohmic electrode pad 2 through the bonding wire 9C to the gate drive terminal 7 makes it possible to separate a high current power loop and a gate drive loop for the gate drive circuit 11. With this structure, it is possible to reduce the voltage noise which is a disturbance noise to the gate drive circuit 11.

It is to be noted that the nitride semiconductor element shown in FIGS. 2A to 2C may be a MESFET in which a Schottky gate electrode is used.

Furthermore, a connection material which connects each electrode pad and an electrode may be an Al ribbon or a clip material made of Cu other than the bonding wire.

Moreover, the substrate terminal 4 may be used as the gate drive terminal 7 by connecting the ohmic electrode pad 2 to the substrate 23, depending on a circuit configuration of the semiconductor device 100. This successfully stabilizes the substrate potential of the nitride semiconductor element, which becomes the very effective measures against the disturbance noise.

### Embodiment 2

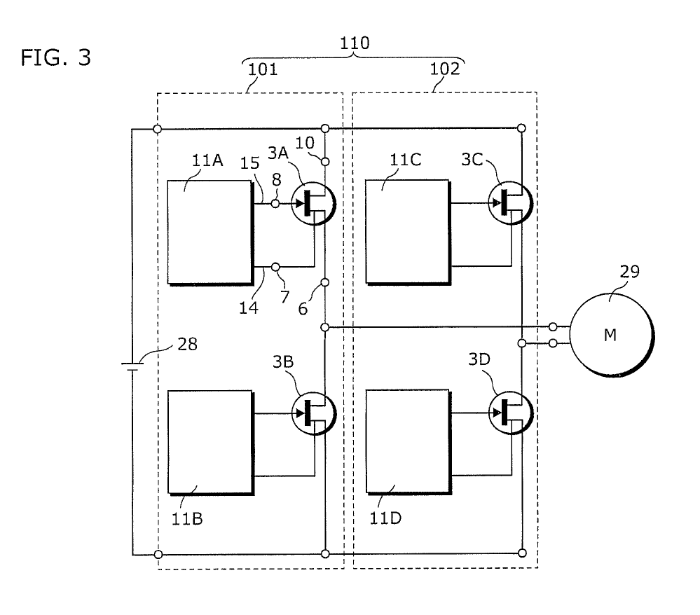

FIG. 3 is a circuit configuration diagram showing a semiconductor device according to Embodiment 2 of the present invention. A drive system shown in the diagram is a system which causes a single-phase inverter circuit to drive a motor and includes a DC power supply 28, a semiconductor device 110, and a motor 29.

The semiconductor device 110 includes a half bridge 101 which is a first half bridge and a half bridge 102 which is a second half bridge. The half bridges 101 and 102 have the same structure, and each of the half bridges 101 and 102 includes the structure of the semiconductor device 100 described in Embodiment 1. To put it differently, each of semiconductor elements 3A to 3D shown in FIG. 3 has the same structure as the semiconductor element 3 shown in FIG. 1. Furthermore, each of gate drive circuits 11A to 11D shown in FIG. 3 has the same configuration as the gate drive circuit 11 shown in FIG. 1. Moreover, the half bridges 101 and 102 are connected in parallel to each other. A point midway between the semiconductor elements 3A and 3B, which are included in the half bridge 101 and are respectively the first semiconductor element and the second semiconductor element, is electrically connected to one of terminals of the motor 29. A point midway between the semiconductor elements 3C and 3D, which are included in the half bridge 102, is electrically connected to the other one of the terminals of the motor 29. Here, the gate drive circuits 11A and 11C which are the first gate drive circuit, that is, the reference potential terminal 14 on a high voltage side is connected to, for instance, each of the above-mentioned midway points, and the gate drive circuits 11B and 11D which are the second gate drive circuit, that is, the reference potential terminal 14 on a low voltage side is connected to, for example, a GND of the semiconductor device 110. This makes it possible to reduce the disturbance noise to each gate drive circuit.

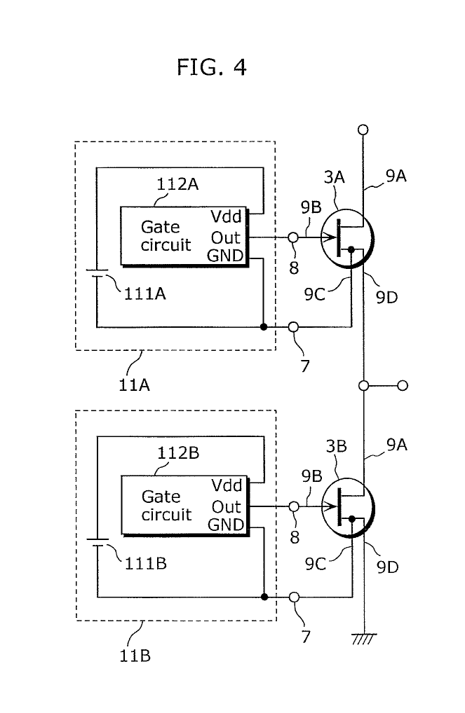

FIG. 4 is an equivalent circuit diagram of a chief part of a half bridge according to Embodiment 2 of the present invention. The gate drive circuit 11A is a first gate drive circuit which is current driven and includes a DC power supply 111A and a gate circuit 112A. A cathode of the DC power supply 111A is electrically connected to a power supply terminal Vdd of the gate circuit 112A, and an anode of the DC power supply 111A is electrically connected to a reference potential terminal GND of the gate circuit 112A. In this case, a power line composed of the DC power supply 28, the ohmic electrode terminal 10, the semiconductor element 3A, the ohmic electrode terminal 6, and the motor 29, which are shown in FIG. 3, and a gate drive line composed of the DC power supply 111A, the gate circuit 112A, the gate terminal 8, the semiconductor element 3A, and the gate drive terminal 7 form separate current lines. Furthermore, the reference potential terminal 14 of the gate drive circuit 11A is electrically connected to the ohmic electrode pad 2 through the bonding wire 9C, and thus a potential of the ohmic electrode pad 2 corresponds to a reference potential of the gate drive circuit 11 which is current driven.

Moreover, the gate drive circuits 11B to 11D have the same configuration as the gate drive circuit 11A.

With this, it is unnecessary to separately provide a GND terminal of the gate drive circuit to other paths of the power line and the gate drive line in the semiconductor device 110. Furthermore, the gate drive line is not influenced by a voltage noise generated in a transient state of the semiconductor elements 3A to 3D by a parasitic inductance of the power line, and thus the gate drive circuits 11A to 11D make it possible to perform highly accurate and stable gate drive.

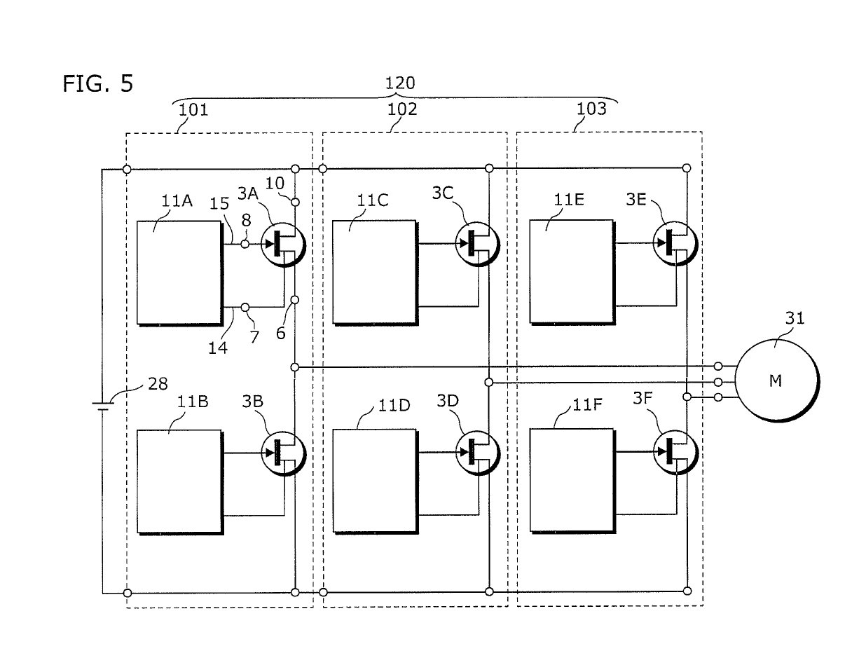

FIG. 5 is a circuit configuration diagram showing a modification of the semiconductor device according to Embodiment 2 of the present invention. A drive system shown in the diagram is a system which causes a three-phase inverter circuit to drive a motor and includes the DC power supply 28, a semiconductor device 120, and a motor 31.

The semiconductor device 120 includes the half bridge 101, the half bridge 102, and a half bridge 103 which is a third half bridge. The half bridges 101 to 103 have the same structure, and each of the half bridges 101 to 103 includes the structure of the semiconductor device 100 described in Embodiment 1. To put it differently, each of semiconductor elements 3A to 3F shown in FIG. 3 has the same structure as the semiconductor element 3 shown in FIG. 1. Furthermore, each of gate drive circuits 11A to 11F shown in FIG. 3 has the same configuration as the gate drive circuit 11 shown in FIG. 1. Moreover, the half bridges 101 to 103 are connected in parallel to each other. A point midway between the semiconductor elements 3A and 3B included in the half bridge 101 is electrically connected to a first terminal of the motor 31, a point midway between the semiconductor elements 3C and 3D included in the half bridge 102 is connected to a second terminal of the motor 31, and a point midway between the semiconductor elements 3E and 3F is electrically connected to a third terminal of the motor 31. Here, the gate drive circuits 11A, 11C, and 11E, that is, the reference potential terminal 14 on the high voltage side is connected to, for instance, each of the above-mentioned midway points, and the gate drive circuits 11B, 11D, and 11F, that is, the reference potential terminal 14 on the low voltage side is connected to, for example, the GND of the semiconductor device 110. This makes it possible to reduce the disturbance noise to each gate drive circuit.

### Embodiment 3

Embodiment 3 describes a structure and effects of a semiconductor device including a double-gate semiconductor element when the present invention is applied, with reference to the drawings. Two gate electrodes placed between the drain and the source are independently controlled, and thus it is possible to control a drain current of the semiconductor element with high accuracy or in a complex manner.

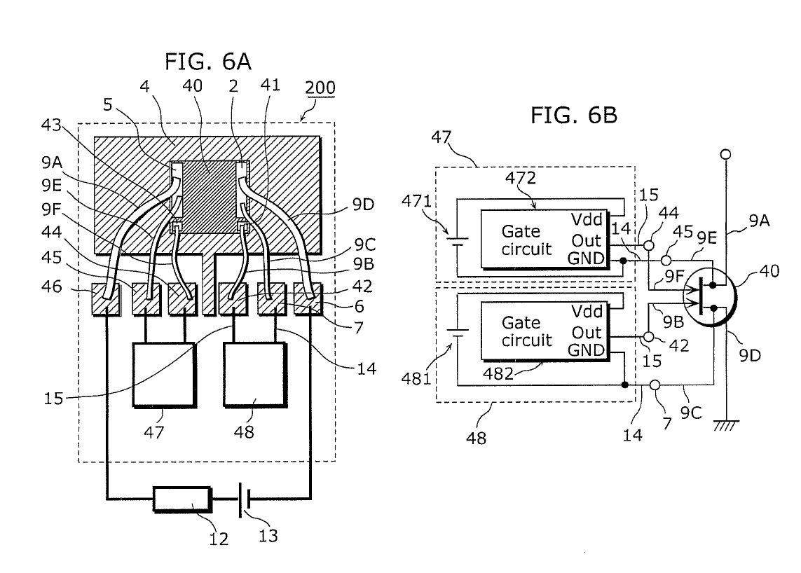

FIG. 6A is a top view illustrating a connection of the semiconductor device according to Embodiment 3 of the present invention. The semiconductor device 200 shown in the view includes: a semiconductor element 40 which is a third semiconductor element; bonding wires 9A to 9F which are connection materials; a gate drive circuit 47 which is a fourth gate drive circuit; and a gate drive circuit 48 which is a third gate drive circuit. Furthermore, the substrate terminal 4, the ohmic electrode terminal 6 and an ohmic electrode terminal 46 which are respectively a third ohmic electrode terminal and a fourth ohmic electrode terminal, the gate drive terminal 7 and a gate drive terminal 45 which are respectively a first gate drive terminal and a second gate drive terminal, and a gate terminal 42 and a gate terminal 44 which are respectively a first gate terminal and a second gate terminal are placed above the semiconductor device 200 in a manner such that they separate from each other. Moreover, the semiconductor element 40 is joined onto the substrate terminal 4, and a gate electrode pad 41 and a gate electrode pad 43 which are respectively a first gate electrode pad and a second gate electrode pad and the ohmic electrode pad 2 and the ohmic electrode pad 5 which are respectively the third ohmic electrode pad and the fourth ohmic electrode pad are placed on the semiconductor element 3 in a manner such that they separate from each other.

The ohmic electrode pad 5 is electrically connected to the ohmic electrode terminal 46 through the bonding wire 9A, and is also separately and electrically connected to the gate drive terminal 45 through the bonding wire 9E. Furthermore, the ohmic electrode pad 2 is electrically connected to the ohmic electrode terminal 6 through the bonding wire 9D, and is also separately and electrically connected to the gate drive terminal 7 through the bonding wire 9C. Moreover, the gate electrode pad 41 is electrically connected to the gate terminal 42 through the bonding wire 9B, and the gate electrode pad 43 is electrically connected to the gate terminal 44 through the bonding wire 9F. The bonding wires 9A to 9F are made of, for example, Al.

The ohmic electrode terminal 46 is electrically connected to one of the terminals of the load 12, and the ohmic electrode terminal 6 is electrically connected to the anode of the DC power supply 13. Furthermore, the other one of the terminals of the load 12 is electrically connected to the cathode of the DC power supply 13. With the above connections, the semiconductor element 40, the ohmic electrode pad 2, which is placed on the semiconductor element 40, the bonding wire 9D, the ohmic electrode terminal 6, the DC power supply 13, the load 12, the ohmic electrode terminal 46, the bonding wire 9A, and the ohmic electrode pad 5 compose a power line.

The gate drive circuit 48 includes the output terminal 15, the reference potential terminal 14 which is the input terminal, and the DC power supply for driving the gate drive circuit (not shown). The output terminal 15 is electrically connected to the gate terminal 42, and the reference potential terminal 14 is electrically connected to the gate drive terminal 7. With the above connections, the semiconductor element 40, the ohmic electrode pad 2, the bonding wire 9C, the gate drive terminal 7, the gate drive circuit 48, the gate terminal 42, the bonding wire 9B, and the gate electrode pad 41 compose a gate drive line. In other words, the gate drive circuit 48 receives a gate-source current, which is defined by a gate-source resistance of the semiconductor element 40, through the ohmic electrode pad 2, the bonding wire 9C, and the gate drive terminal 7, and determines, using the received current, an electrical signal which is for controlling power conversion by the semiconductor element 40 and which is to be provided to the gate.

The gate drive circuit 47 has the same configuration as the gate drive circuit 48. With the connection of the gate drive circuit 47, the semiconductor element 40, the ohmic electrode pad 5, the bonding wire 9E, the gate drive terminal 45, the gate drive circuit 47, the gate terminal 44, the bonding wire 9F, and the gate electrode pad 43 compose a gate drive line. In other words, the gate drive circuit 47 receives a gate-drain current, which is defined by a gate-drain resistance of the semiconductor element 40, through the ohmic electrode pad 5, the bonding wire 9E, and the gate drive terminal 45, and determines, using the received current, an electrical signal which is for controlling power conversion by the semiconductor element 40 and which is to be provided to the gate.

FIG. 6B is an equivalent circuit diagram of a chief part of the semiconductor device according to Embodiment 3 of the present invention. The gate drive circuit 47 is a current-driven circuit which includes a DC power supply 471 and a gate circuit 472. A cathode of the DC power supply 471 is electrically connected to a power supply terminal Vdd of the gate circuit 472, and an anode of the DC power supply 471 is electrically connected to a reference potential terminal GND of the gate circuit 472. In this case, the power line illustrated in FIG. 6A and the gate drive line form separate current lines. Furthermore, the reference potential terminal 14 of the gate drive circuit 47 is electrically connected to the ohmic electrode pad 5 through the bonding wire 9E, and thus a potential of the ohmic electrode pad 5 corresponds to a reference potential of the gate drive circuit 47 which is current driven.

The gate drive circuit 48 is a current-driven circuit which includes a DC power supply 481 and a gate circuit 482. A cathode of the DC power supply 481 is electrically connected to a power supply terminal Vdd of the gate circuit 482, and an anode of the DC power supply 481 is electrically connected to a reference potential terminal GND of the gate circuit 482. In this case, the power line illustrated in FIG. 6A and the gate drive line form separate current lines. Moreover, the reference potential terminal 14 of the gate drive circuit 48 is electrically connected to the ohmic electrode pad 2 through the bonding wire 9C, and thus a potential of the ohmic electrode pad 2 corresponds to a reference potential of the gate drive circuit 48 which is current driven.

With this, it is unnecessary to separately provide a GND terminal of the gate drive circuit to other paths of the power line and the gate drive line in the semiconductor device 200. Furthermore, the gate drive line is not influenced by a voltage noise generated in a transient state of the semiconductor element 40 by a parasitic inductance of the power line, and thus each of the gate drive circuits 47 and 48 makes it possible to independently perform highly accurate and stable gate drive.

It is to be noted that although, in the above structure, the potentials of the ohmic electrode pads 5 and 2 respectively correspond to the reference potentials of the gate drive circuits 47 and 48 and it is possible to set the potentials of the ohmic electrode pads 5 and 2 independently of the GND potential of the semiconductor device 200, the potential of the ohmic electrode pad 2 may correspond to the GND potential of the semiconductor device 200 depending on use and configuration of the gate drive circuits 47 and 48. In this case also, it is possible to produce the same effects as the effects obtained through the structure. In addition, it is possible to stabilize a substrate potential of the semiconductor device 200, which is very effective as measures against disturbance noise.

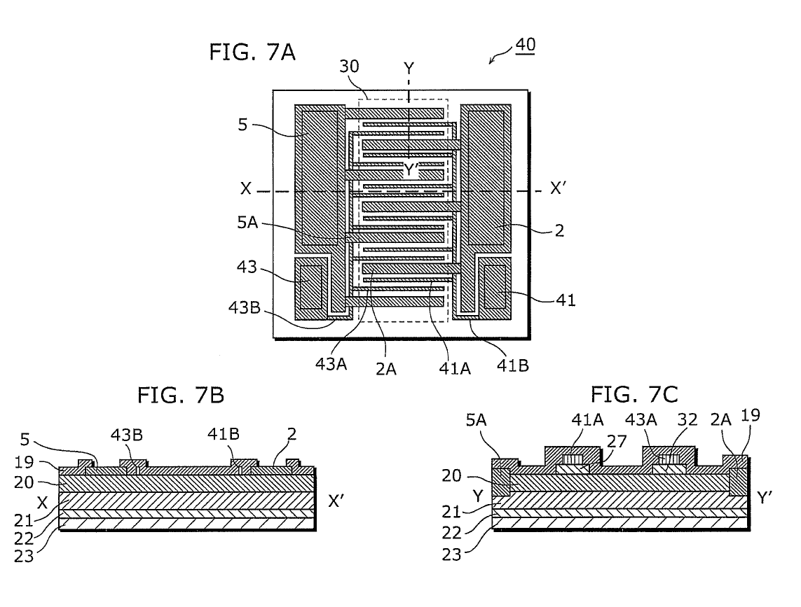

FIG. 7A is a top view illustrating the semiconductor element according to Embodiment 3 of the present invention. FIG. 7B is a cross-sectional view taken along the line X-X′ of the semiconductor element illustrated in FIG. 7A. FIG. 7C is a cross-sectional view taken along the line Y-Y′ of the semiconductor element illustrated in FIG. 7A. The semiconductor element 40 shown in FIG. 7A is, for instance, a nitride semiconductor element in which a two-dimensional electron gas (2 DEG) including heterojunction of AlGaN/GaN is used as a channel.

As shown in FIGS. 7A to 7C, in the semiconductor element 40, the buffer layer 22, the nitride semiconductor layers 21 and 20, and p-type nitride semiconductor layers 27 and 32 are sequentially stacked on the substrate 23, gate electrodes 41A and 43A and the ohmic electrodes 2A and 5A are formed, and the protective film 19 is formed. The buffer layer 22, the nitride semiconductor layers 21 and 20, and the p-type nitride semiconductor layers 27 and 32 form a stacked structure including nitride semiconductor layers. The ohmic electrode pads 2 and 5 are respectively connected to ohmic electrode 2A which is the third ohmic electrode and the ohmic electrode 5A which is the fourth ohmic electrode. The gate electrode pads 41 and 43 are respectively connected to the gate electrode 41A which is the first gate electrode and the gate electrode 43A which is the second gate electrode. Each of the gate electrode pads 41 and 43 is formed in the opening of the protective film 19. Moreover, the ohmic electrodes 5A and 2A and the gate electrodes 41A and 43A form, in the active region 30, the finger shape as shown in FIG. 7A. In other words, the gate electrodes 5A and 2A are placed between the ohmic electrodes 41A and 43A in this order. The semiconductor element 40 having the above structure is, for instance, a switching element which switches on and off a power line to which the DC power supply 13 shown in FIG. 6A applies the voltage value of 300 V to pass the current of approximately 10 A.

The nitride semiconductor element as shown in FIGS. 7A to 7C has a very small parasitic capacitance between each of terminals such as several tens of pF to several hundreds of pF, and thus enables high-speed switching at a several tens of ns to several hundreds of ns level in comparison with a MOSFET or an IGBT. However, the faster the above switching is, the more a voltage noise, which is a product of a parasitic inductance L of, for example, a wire, a lead, and a wiring pattern and di/dt, is generated. As stated above, the voltage noise causes the malfunction such as the false detection of the gate in gate drive, and thus it is necessary to reduce the voltage noise.

In order to reduce the above voltage noise, as shown in FIG. 6A, more specifically, the potentials of the ohmic electrode pads 5 and 2 respectively correspond to the reference potentials of the gate drive circuits 47 and 48. Separating a current path from the ohmic electrode pad 5 through the bonding wire 9A to the ohmic electrode terminal 46 and a current path from the ohmic electrode pad 5 through the bonding wire 9E to the gate drive terminal 45 makes it possible to separate a high current power loop and a gate drive loop for the gate drive circuit 47. With the same connection as the connection of the ohmic electrode pad 2, it is possible to separate the high current power loop and a gate drive loop for the gate drive circuit 48. With this structure, it is possible to reduce the voltage noise which is a disturbance noise to the gate drive circuits 47 and 48.

It is to be noted that the nitride semiconductor element shown in FIGS. 7A to 7C may be the MESFET in which the Schottky gate electrode is used.

Furthermore, the connection material which connects each electrode pad and the electrode may be the Al ribbon or the clip material made of Cu other than the bonding wire.

Moreover, the substrate terminal 4 may be used as the gate drive terminal 7 by connecting the ohmic electrode pad 2 to the substrate 23, depending on the circuit configuration of the semiconductor device 200. This successfully stabilizes the substrate potential of the nitride semiconductor element, which becomes the very effective measures against the disturbance noise.

### Embodiment 4

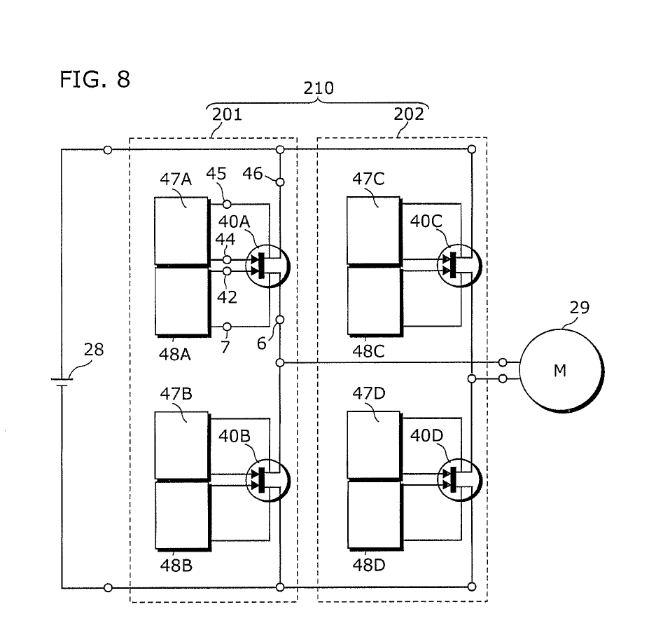

FIG. 8 is a circuit configuration diagram showing a semiconductor device according to Embodiment 4 of the present invention. A drive system shown in the diagram is a system which causes a single-phase inverter circuit to drive a motor and includes the DC power supply 28, a semiconductor device 210, and the motor 29.

The semiconductor device 210 includes a half bridge 201 which is a fourth half bridge and a half bridge 202 which is a fifth half bridge. The half bridges 201 and 202 have the same structure, and each of the half bridges 201 and 202 includes the structure of the semiconductor device 200 which is a double-gate type and is described in Embodiment 3. To put it differently, each of semiconductor elements 40A to 40D shown in FIG. 8 has the same structure as the semiconductor element 40 shown in FIG. 6. Gate drive circuits 47A and 47C, which are shown in FIG. 8 and are the fourth gate drive circuit, and gate drive circuits 47B and 47D, which are shown in FIG. 8 and are a sixth gate drive circuit, each have the same configuration as the gate drive circuit 47 shown in FIG. 6. Gate drive circuits 48A and 48C, which are shown in FIG. 8 and are the third gate drive circuit, and gate drive circuits 48B and 48D, which are shown in FIG. 8 and are a fifth gate drive circuit, each have the same configuration as the gate drive circuit 48 shown in FIG. 5. Moreover, the half bridges 201 and 202 are connected in parallel to each other. A point midway between the semiconductor elements 40A and 40B, which are included in the half bridge 201 and are respectively the third semiconductor element and a fourth semiconductor element, is electrically connected to one of the terminals of the motor 29. A point midway between the semiconductor elements 40C and 40D, which are included in the half bridge 202 and are respectively the third semiconductor element and the fourth semiconductor element, is electrically connected to the other one of the terminals of the motor 29.

Here, the reference potential terminal 14 of each of the gate drive circuits 48A and 48C is connected to, for instance, each of the above midway points, the reference potential terminal 14 of each of the gate drive circuits 47A and 47C is electrically connected to, for example, a cathode of the DC power supply 28, the reference potential terminal 14 of each of the gate drive circuits 48B and 48D is electrically connected to, for instance, a GND terminal of the semiconductor device 210, and the reference potential terminal 14 of each of the gate drive circuits 47B and 47D is connected to, for example, each of the above midway points. This makes it possible to reduce the disturbance noise to each gate drive circuit.

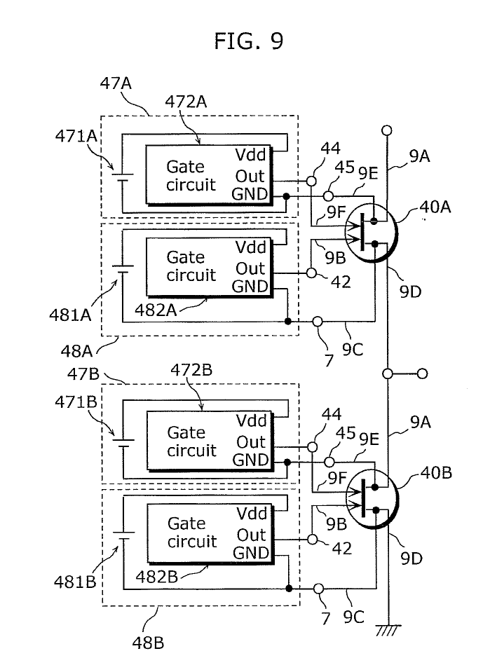

FIG. 9 is an equivalent circuit diagram of a chief part of a half bridge according to Embodiment 4 of the present invention. A gate drive circuit 47A is a current-driven circuit which includes a DC power supply 471A and a gate circuit 472A. A cathode of the DC power supply 471A is electrically connected to a power supply terminal Vdd of the gate circuit 472A, and an anode of the DC power supply 471A is electrically connected to a reference potential terminal GND of the gate circuit 472A. A gate drive circuit 48A is a DC circuit which includes a DC power supply 481A and a gate circuit 482A. A cathode of the DC power supply 481A is electrically connected to a power supply terminal Vdd of the gate circuit 482A, and an anode of the DC power supply 481A is electrically connected to a reference potential terminal GND of the gate circuit 482A.

In this case, a power line composed of the DC power supply 28, the ohmic electrode terminal 46, and the motor 29, which are shown in FIG. 8, and a gate drive line composed of the DC power supply 471A, the gate circuit 472A, the gate terminal 44, the semiconductor element 40A, and the gate drive terminal 45 form separate current lines. Likewise, the above power line and a gate drive line composed of the DC power supply 481A, the gate circuit 482A, the gate terminal 42, the semiconductor element 40A, and the gate drive terminal 7 form separate current lines.

Furthermore, the reference potential terminal 14 of the gate drive circuit 47A is electrically connected to the ohmic electrode pad 5 through the bonding wire 9E, and thus a potential of the ohmic electrode pad 5 corresponds to a reference potential of the gate drive circuit 47A which is current driven.

Moreover, the reference potential terminal 14 of the gate drive circuit 48A is electrically connected to the ohmic electrode pad 2 through the bonding wire 9C, and thus a potential of the ohmic electrode pad 2 corresponds to a reference potential of the gate drive circuit 48A which is current driven.

The gate drive circuits 47B to 47D have the same configuration as the gate drive circuit 47A.

Furthermore, the gate drive circuits 48B to 48D have the same configuration as the gate drive circuit 48A.

With this, it is unnecessary to separately provide a GND terminal of the gate drive circuit to other paths of the power line and the gate drive line in the semiconductor device 210. Moreover, the gate drive line is not influenced by a voltage noise generated in a transient state of the semiconductor elements 40A to 40D by a parasitic inductance of the power line, and thus the gate drive circuits 47A to 47D and 48A to 48D make it possible to perform highly accurate and stable gate drive.

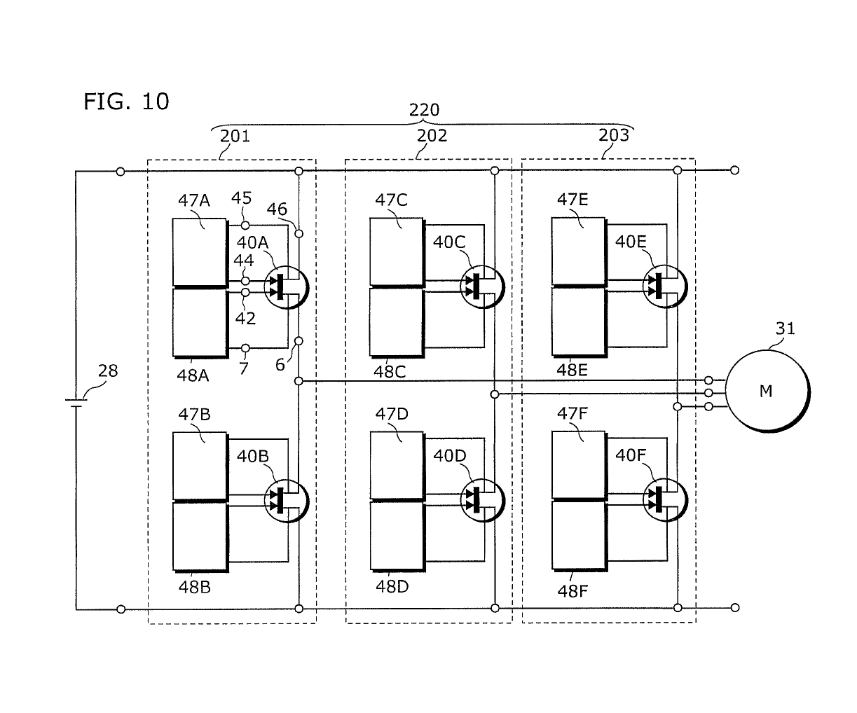

FIG. 10 is a circuit configuration diagram showing a first modification of the semiconductor device according to Embodiment 4 of the present invention. A drive system shown in the diagram is a system which causes a three-phase inverter circuit to drive a motor and includes the DC power supply 28, the semiconductor device 220, and the motor 31.

The semiconductor device 220 includes the half bridges 201 and 202, and a half bridge 203 which is a sixth half bridge. The half bridges 201 to 203 have the same structure, and each of the half bridges 201 to 203 includes the structure of the semiconductor device 200 which is the double-gate type and is described in Embodiment 3. To put it differently, each of semiconductor elements 40A to 40F shown in FIG. 10 has the same structure as the semiconductor element 40 shown in FIG. 6. Furthermore, each of gate drive circuits 47A to 47F shown in FIG. 10 has the same configuration as the gate drive circuit 47 shown in FIG. 6. Moreover, the half bridges 201 to 203 are connected in parallel to each other. A point midway between the semiconductor elements 40A and 40B included in the half bridge 201 is electrically connected to the first terminal of the motor 31, a point midway between the semiconductor elements 40C and 40D included in the half bridge 202 is connected to the second terminal of the motor 31, and a point midway between the semiconductor elements 40E and 40F is electrically connected to the third terminal of the motor 31.

Here, the reference potential terminal 14 of each of the gate drive circuits 48A, 48C, and 48E is connected to, for instance, the midway point of each half bridge, the reference potential terminal 14 of each of the gate drive circuits 47A, 47C, and 47E is electrically connected to, for example, the cathode of the DC power supply 28, the reference potential terminal 14 of each of the gate drive circuits 48B, 48D, and 48F is connected to, for instance, the GND terminal of the semiconductor device 220, and the reference potential terminal 14 of each of the gate drive circuits 47B, 47D, and 47F is connected to, for example, the midway point of each half bridge. This makes it possible to reduce the disturbance noise to each gate drive circuit.

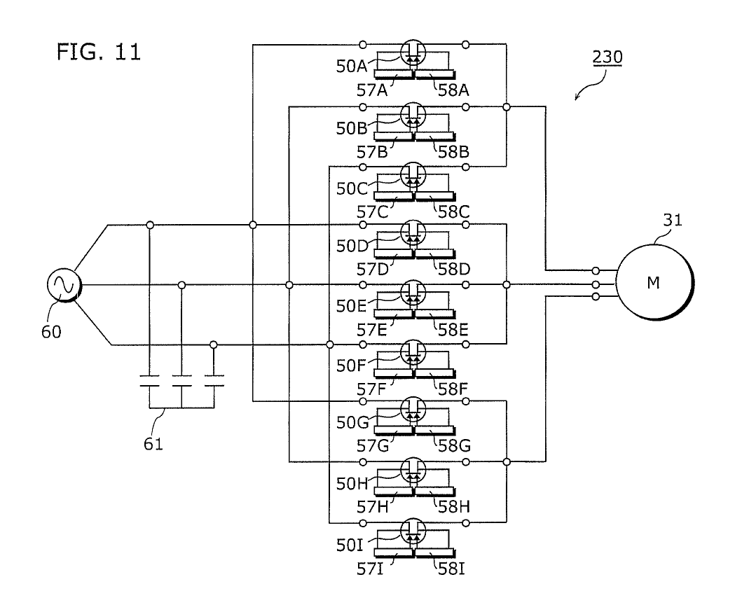

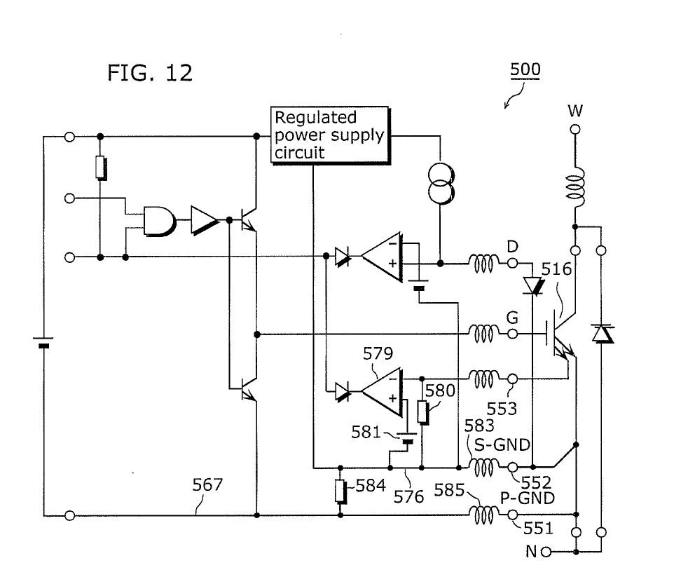

FIG. 11 is a circuit configuration diagram showing a second modification of the semiconductor device according to Embodiment 4 of the present invention. A drive system shown in the diagram is a system which causes a three-phase inverter circuit to drive a motor and includes an AC power supply 60, an input filter 61, a semiconductor device 230, and the motor 31.

Each of semiconductor elements 50A to 50I has the same structure as the semiconductor element 40 which is a double-gate type and is shown in FIG. 6. Furthermore, each of gate drive circuits 57A to 57I shown in FIG. 11 has the same configuration as the gate drive circuit 47 shown in FIG. 6. Moreover, each of gate drive circuits 58A to 58I shown in FIG. 11 has the same configuration as the gate drive circuit 48 shown in FIG. 6.

The AC power supply 60 provides three-phase AC power, and the input filter 61 is connected between each of phases of the three-phase inputs. The gate drive circuits 58A and 57A and the semiconductor element 50A which is a double-gate type compose a single unit, and nine such units are arranged. Stated differently, the single unit causes the two gate drive circuits to drive the single double-gate semiconductor element. The nine units provide three-phase output currents to the motor 31 by forming three-phase matrix converter circuits.

More specifically, the semiconductor device 230 has the following structure.

The ohmic electrode terminal 46 of each of the semiconductor elements 50A, 50D, and 50G, which are respectively the third semiconductor element, a sixth semiconductor element, and a ninth semiconductor element, is connected to a first output terminal of a three-phase AC power supply.

The ohmic electrode terminal 46 of each of the semiconductor elements 50B, 50E, and 50H, which are respectively the fourth semiconductor element, a seventh semiconductor element, and a tenth semiconductor element, is connected to a second output terminal of the three-phase AC power supply.

The ohmic electrode terminal 46 of each of the semiconductor elements 50C, 50F, and 50I, which are respectively a fifth semiconductor element, an eighth semiconductor element, and an eleventh semiconductor element, is connected to a third output terminal of the three-phase AC power supply.

The ohmic electrode terminal 6 of each of the semiconductor elements 50A to 50C is connected to a first input terminal of a three-phase motor.

The ohmic electrode terminal 6 of each of the semiconductor elements 50D to 50F is connected to a second input terminal of the three-phase motor.

The ohmic electrode terminal 6 of each of the semiconductor elements 50G to 50I is connected to a third input terminal of the three-phase motor.

Here, the reference potential terminal 14 of each of the gate drive circuits 57A to 57I is connected to, for instance, a terminal on an input side, and the reference potential terminal 14 of each of the gate drive circuits 58A to 58I is connected to, for example, a terminal on an output side. This makes it possible to reduce the disturbance noise to each gate drive circuit.

It is preferred that the reference potential of each unit corresponds not to a reference potential of a drive system but to an arbitrary reference potential, because the reference potential of the drive system varies when an input power supply is an AC power supply. According to the above structure, the potential of the ohmic electrode pad 2 or the ohmic electrode pad 5, which is a current-driven source pad, corresponds to the reference potential of each unit, and thus the reference potential of each unit does not need to be identical to the reference potential of the semiconductor device, and it is possible to operate the gate drive circuits independently.

Although the semiconductor device of the present invention has been described above based on the embodiments, the semiconductor device according to the present invention is not limited to the embodiments. The present invention includes: other embodiments realized by combining any elements in Embodiments 1 to 4 and modifications thereof; modifications obtained by applying, within the scope of the present invention, various modifications conceived by those skilled in the art to Embodiments 1 to 4 and the modifications thereof; and various apparatuses including the semiconductor device according to the present invention.

### INDUSTRIAL APPLICABILITY

The present invention is applicable to gate drive control of high-power devices which require highly accurate and stable power control, and is suitable for application to current-driven semiconductor devices.

What is claimed is:

1. A semiconductor device comprising:
a first semiconductor element which is current driven and performs power conversion;
a first gate drive circuit which controls the power conversion by said first semiconductor element; and
a connection terminal unit,
wherein said first semiconductor element includes:
a stacked structure including nitride semiconductor layers stacked above a substrate;
a gate electrode formed on said stacked structure;
a first ohmic electrode and a second ohmic electrode each of which is formed, above the substrate, on a different side of said gate electrode;
a gate electrode pad wired from said gate electrode on said first semiconductor element; and
a first ohmic electrode pad and a second ohmic electrode pad respectively wired from said first ohmic electrode and said second ohmic electrode on said first semiconductor element,
wherein said connection terminal unit includes:
a first ohmic electrode terminal connected to said first ohmic electrode pad through a first connection material;
a second ohmic electrode terminal connected to said second ohmic electrode pad through a second connection material;
a gate drive terminal connected to said first ohmic electrode pad through a third connection material; and
a gate terminal connected to said gate electrode pad through a fourth connection material, and
an input terminal and an output terminal of said first gate drive circuit are respectively connected to said gate drive terminal and said gate terminal, and a potential of said first ohmic electrode pad corresponds to a reference potential of said first gate drive circuit.

2. The semiconductor device according to claim 1,
wherein said connection terminal unit further includes a first substrate terminal joined to said first semiconductor element, and
said gate drive terminal is identical to said first substrate terminal.

3. The semiconductor device according to claim 1, further comprising:
a second semiconductor element having a same structure as said first semiconductor element; and
a second gate drive circuit having a same structure as said first gate drive circuit,
wherein a connection relationship between said second semiconductor element and said second gate drive circuit is the same as a connection relationship between said first semiconductor element and said first gate drive circuit, and
said first semiconductor element, said second semiconductor element, said first gate drive circuit, and said second gate drive circuit form a first half bridge by connecting said first ohmic electrode terminal of said first semiconductor element and said second ohmic electrode terminal of said second semiconductor element.

4. The semiconductor device according to claim 3, further comprising
a second half bridge which is connected in parallel to said first half bridge and has a same structure as said first half bridge,
wherein said semiconductor device functions as a motor drive inverter which drives a single-phase motor.

5. The semiconductor device according to claim 3, further comprising
a second half bridge and a third half bridge which are connected in parallel to said first half bridge and have a same structure as said first half bridge,
wherein said semiconductor device functions as a motor drive inverter which drives a three-phase motor.

6. A semiconductor device comprising:
a third semiconductor element which is current driven and performs power conversion;
a third gate drive circuit and a fourth gate drive circuit which control the power conversion by said third semiconductor element; and
a connection terminal unit,
wherein said third semiconductor element includes:
a stacked structure including nitride semiconductor layers stacked above a substrate;
a first gate electrode and a second gate electrode formed adjacent to each other on said stacked structure;
a third ohmic electrode and a fourth ohmic electrode each of which is formed, above the substrate, on a different side of said first gate electrode and said second gate electrode;
a first gate electrode pad and a second gate electrode pad respectively wired from said first gate electrode and said second gate electrode on said third semiconductor element; and
a third ohmic electrode pad and a fourth ohmic electrode pad respectively wired from said third ohmic electrode and said fourth ohmic electrode on said third semiconductor element,
said connection terminal unit includes:
a third ohmic electrode terminal connected to said third ohmic electrode pad through a first connection material;
a fourth ohmic electrode terminal connected to said fourth ohmic electrode pad through a second connection material;
a first gate drive terminal connected to said third ohmic electrode pad through a third connection material;
a second gate drive terminal connected to said fourth ohmic electrode pad through a fourth connection material;
a first gate terminal connected to said first gate electrode pad through a fifth connection material; and
a second gate terminal connected to said second gate electrode pad through a sixth connection material,
an input terminal and an output terminal of said third gate drive circuit are respectively connected to said first gate drive terminal and said first gate terminal, and a potential of said third ohmic electrode pad corresponds to a reference potential of said third gate drive circuit, and
an input terminal and an output terminal of said fourth gate drive circuit are respectively connected to said second gate drive terminal and said second gate terminal, and a potential of said fourth ohmic electrode pad corresponds to a reference potential of said fourth gate drive circuit.

7. The semiconductor device according to claim 6, further comprising:
a fourth semiconductor element having a same structure as said third semiconductor element;
a fifth gate drive circuit having a same structure as said third gate drive circuit; and
a sixth gate drive circuit having a same structure as said fourth gate drive circuit,
wherein a connection relationship between said fourth semiconductor element and said fifth gate drive circuit is the same as a connection relationship between said third semiconductor element and said third gate drive circuit,
a connection relationship between said fourth semiconductor element and said sixth gate drive circuit is the same as a connection relationship between said third semiconductor element and said fourth gate drive circuit, and
said third semiconductor element, said fourth semiconductor element, said third gate drive circuit, said fourth gate drive circuit, said fifth gate drive circuit, and said sixth gate drive circuit form a fourth half bridge by connecting said third ohmic electrode terminal of said third semiconductor element and said fourth ohmic electrode terminal of said fourth semiconductor element.

8. The semiconductor device according to claim 7, further comprising
a fifth half bridge which is connected in parallel to said fourth half bridge and has a same structure as said fourth half bridge,
wherein said semiconductor device functions as a motor drive inverter which drives a single-phase motor.

9. The semiconductor device according to claim 7, further comprising
a fifth half bridge and a sixth half bridge which are connected in parallel to said fourth half bridge and have a same structure as said fourth half bridge,
wherein said semiconductor device functions as a motor drive inverter which drives a three-phase motor.

10. The semiconductor device according to claim 6, further comprising
fourth to eleventh semiconductor elements having a same structure as said third semiconductor element,
wherein each of said fourth to eleventh semiconductor elements is connected to a gate drive circuit having a same structure as said third gate drive circuit and a gate having a same structure as said fourth gate drive circuit,
said fourth ohmic electrode terminal of each of said third, sixth, and ninth semiconductor elements is connected to a first output terminal of a three-phase alternating-current power supply,
said fourth ohmic electrode terminal of each of said fourth, seventh, and tenth semiconductor elements is connected to a second output terminal of the three-phase alternating-current power supply,
said fourth ohmic electrode terminal of each of said fifth, eighth, and eleventh semiconductor elements is connected to a third output terminal of the three-phase alternating-current power supply,
said third ohmic electrode terminal of each of said third, fourth, and fifth semiconductor elements is connected to a first input terminal of a three-phase motor,
said third ohmic electrode terminal of each of said sixth, seventh, and eighth semiconductor elements is connected to a second input terminal of the three-phase motor,
said third ohmic electrode terminal of each of said ninth, tenth, and eleventh semiconductor elements is connected to a third input terminal of the three-phase motor, and
said semiconductor device functions as a motor drive matrix converter which drives the three-phase motor.
